(19) United States
(12) Patent Application Publication
(10) Pub. No.: US 2026/0342045 A1
(43) Pub. Date: Oct. 29, 2026

(54) LASER ARRAYS WITH COMPENSATED GRATINGS

(71) Applicant: MACOM Technology Solutions Holdings, Inc., Lowell, MA (US)

(72) Inventors: Yueyang Yu, Dracut, MA (US); Wolfgang Parz, Ithaca, NY (US)

(21) Appl. No.: 19/193,215

(22) Filed: Apr. 29, 2025

(51) Int. Cl. H01S 5/12

(52) U.S. Cl. CPC H01S 5/1212

(57) ABSTRACT

A semiconductor laser includes an active region having a length along a longitudinal direction thereof and a width along a transverse direction thereof, and one or more active channels each including gratings positioned along the longitudinal direction. The gratings of each active channel have a chirped grating having a non-constant pitch deviated from a target pitch by a pitch adjustment value based on a spatial variance in a parameter of the active channels associated with operating of the semiconductor laser.

### FIELD

The present disclosure relates to semiconductor photonic devices and in particular to laser arrays and single channel laser devices.

### BACKGROUND

A laser array that adheres to the multi-source agreement (MSA) standard refers to an MSA-compliant laser array. For example, an MSA-compliant continuous wave (CW) laser array can provide multi-channel high power CW laser output. Each channel at specific wavelength is defined by the MSA standard. Laser arrays are building blocks of integrated optics and are widely used in inter-chip communication in datacenters. Key characteristics of the laser arrays include high output power, precision of output wavelengths, kink-free operation, and the like. Mode hopping, which is usually observed as a kink on a light-current (LI) curve of a laser device, is one of the most common types of failures and bottleneck of yield enhancement in high power CW lasers.

### SUMMARY

In an exemplary embodiment of the present disclosure, a semiconductor laser is provided. The semiconductor laser includes an active region having a length along a longitudinal direction thereof and a width along a transverse direction thereof, and one or more active channels each comprising a plurality of gratings positioned along the longitudinal direction. Each of the pluralities of gratings of the one or more active channels has a chirped grating having a non-constant pitch. The non-constant pitch is deviated from the target pitch by a pitch adjustment value based on a spatial variance in a parameter of the active channels associated with operating of the semiconductor laser. The target pitch corresponds to a channel lasing wavelength.

In an example thereof, the spatial variance in the parameter of the active channels associated with operating of the semiconductor laser includes one or more of i) a temperature spatial variance along one of the longitudinal direction and the transverse direction, ii) a strain spatial variance along one of the longitudinal direction and the transverse direction, and iii) a current density induced refractive index spatial variance along one of the longitudinal direction and the transverse direction.

In another example thereof, the pitch adjustment value is in a range from about 0 to about 0.8 nm for the temperature spatial variance in a range from 0 to 40° C.

In yet another example thereof, the pitch adjustment value is in a range from about −2 to about 2 nm for the strain spatial variance in a range from −1% to 1%.

In a further example thereof, the spatial variance in the parameter of the active channels associated with operating of the semiconductor laser includes a combination of a temperature spatial variance and a strain spatial variance along the longitudinal direction and the transverse direction.

In still another example thereof, the pitch adjustment value is in a range from about −2 to about 2.8 nm for the combination of a temperature spatial variance and a strain spatial variance along the longitudinal direction and the transverse direction.

In yet another example thereof, the one or more active channels are positioned side by side along the transverse direction with a spacing therebetween in a range from 20 micrometers to 250 micrometers.

In yet a further example thereof, the length of the one or more active channels is in a range from 0.5 mm to 5 mm.

In yet a further example thereof, the width of the one or more active channels is in a range from 0.25 mm to 10 mm.

In yet a further example thereof, the channel lasing wavelengths of the one or more active channels have a channel spacing in a range from 3 GHz to 500 GHz.

In yet a further example thereof, the semiconductor laser further includes a substrate, a p-type cladding layer, an n-type cladding layer, an electrode layer. The active region is sandwiched between the p-type cladding layer and the n-type cladding layer, and a bias current is applied on the electrode layer.

In another exemplary embodiment of the present disclosure, a method of making a semiconductor laser is provided. The method includes forming one or more active channels at an active region. The active region has a length along a longitudinal direction thereof and a width along a transverse direction thereof. The one or more active channels each include a plurality of gratings positioned along the longitudinal direction. Each of the pluralities of gratings of the one or more active channels has a chirped grating having a non-constant pitch, the non-constant pitch being deviated from the target pitch by a pitch adjustment value based on a spatial variance in a parameter of the active channels associated with operating of the semiconductor laser. The target pitch corresponds to a channel lasing wavelength.

In an example thereof, the method further includes determining a temperature spatial variance of the active channels along the longitudinal direction and the transverse direction when the one or more active channels emit light simultaneously.

In a further example thereof, the method further includes determining the pitch adjustment value of the one or more active channels based at least in part on the temperature spatial variance.

In another example thereof, the method further includes determining a strain spatial variance of the active channels along the longitudinal direction and the transverse direction when the one or more active channels emit light simultaneously.

In a further example thereof, the method further includes determining the pitch adjustment value of the one or more active channels based at least in part on the strain spatial variance.

In another example thereof, the method further includes determining a refractive index spatial variance along one or both of the longitudinal direction and the transverse direction.

In a further example thereof, the refractive index spatial variance is induced by a bias current applied on an electrode layer of the semiconductor laser.

In a further example thereof, the method further includes determining the pitch adjustment value of the one or more active channels the refractive index spatial variance.

In another example thereof, the method further includes determining the pitch adjustment value of the one or more active channels based on two or more of a temperature spatial variance of the active channels, a strain spatial variance of the active channels, and a refractive index spatial variance.

### BRIEF DESCRIPTION OF THE DRAWINGS

The above-mentioned and other features and advantages of this disclosure, and the manner of attaining them, will become more apparent and will be better understood by reference to the following description of exemplary embodiments taken in conjunction with the accompanying drawings, wherein:

FIG. 1 is a schematic diagram illustrating a CW DFB laser, in accordance with an embodiment of the present disclosure;

FIG. 2A is a diagram illustrating a continuous wave (CW) distributed feedback (DFB) laser array, in accordance with an embodiment of the present disclosure;

FIG. 2B is an emission spectra of the CW DFB layer array of FIG. 2A;

FIG. 2C is a plot illustrating a light-current (LI) characteristic of the CW DFB laser array of FIG. 2A;

FIG. 2D is a plot illustrating a light-current (LI) characteristic of a comparative CW DFB laser array;

FIG. 3A is a plot illustrating temperature profiles along each laser cavity, in accordance with an embodiment of the present disclosure;

FIG. 3B is a plot illustrating calculated lasing mode wavelengths with respect to different grating phases, in accordance with an embodiment of the present disclosure;

FIG. 3C is a plot illustrating a cross-sectional temperature profile of a 16-channel laser array, in accordance with an embodiment of the present disclosure;

FIG. 4 is a diagram illustrating a map of pitch adjustment values (nm) in a CW DFB grating at each section of a laser array, in accordance with an embodiment of the present disclosure.

FIG. 5 is a block diagram illustrating an example method of compensating parameter variance for a semiconductor laser, in accordance with an embodiment of the present disclosure.

Corresponding reference characters indicate corresponding parts throughout the several views. The exemplification set out herein illustrates an exemplary embodiment of the disclosure and such exemplification is not to be construed as limiting the scope of the disclosure in any manner.

### DETAILED DESCRIPTION OF THE DRAWINGS

For the purposes of promoting an understanding of the principles of the present disclosure, reference is now made to the embodiments illustrated in the drawings, which are described below. The embodiments disclosed herein are not intended to be exhaustive or limit the present disclosure to the precise form disclosed in the following detailed description. Rather, the embodiments are chosen and described so that others skilled in the art may utilize their teachings. Therefore, no limitation of the scope of the present disclosure is thereby intended. Corresponding reference characters indicate corresponding parts throughout the several views.

The terms “couples”, “coupled”, “coupler” and variations thereof are used to include both arrangements wherein the two or more components are in direct physical contact and arrangements wherein the two or more components are not in direct contact with each other (e.g., the components are “coupled” via at least a third component), but yet still cooperate or interact with each other.

In some instances throughout this disclosure and in the claims, numeric terminology, such as first, second, third, and fourth, is used in reference to various components or features. Such use is not intended to denote an ordering of the components or features. Rather, numeric terminology is used to assist the reader in identifying the component or features being referenced and should not be narrowly interpreted as providing a specific order of components or features.

There is a desire to improve the performance of a laser array to provide, for example, high output power, precision of output wavelengths, kink-free operation, and the like. For example, mode hopping is typically associated with inhomogeneous strain and thermal conditions around a laser cavity or channel of the laser array, which may distort distributed feedback (DFB) grating(s) of the laser array. During operation of a laser array, heat is generated at the junction of each channel. The generated heat can produce a temperature gradient across the channels (i.e., along a transverse direction) and along the cavity direction of each channel (i.e., along a longitudinal direction). In some instances, the laser array may have an asymmetric layout of the array and a sub-mount configuration, which may further complicate the temperature profile during operation. DFB gratings are periodic structures acting as distributed reflectors that reflect light within the laser cavity, selectively reinforcing certain wavelengths of light and suppressing other wavelengths of light. In the case of laser arrays, the problem of distorting gratings may become more profound as the inhomogeneity is increased by turning-on multiple or all channels simultaneously.

According to certain embodiments, a highly repeatable and cost-effective solution to address the above inhomogeneity issue is provided through compensated gratings including, for example, thermal-profile compensated gratings, strain-profile compensated gratings, refractive-index-profile compensated gratings, and the like. For example, in some embodiments, the thermally compensated gratings can balance the thermal profile generated by the operation of the laser array, leading to a more stabilized optical mode output and higher output power.

According to certain embodiments, a semiconductor laser includes an active region having a length along a longitudinal direction thereof and a width along a transverse direction thereof. An array of active channels is positioned side by side along the transverse direction with a spacing therebetween. In some embodiments, the spacing between the array of active channels is in a range, for example, from 20 micrometers to 250 micrometers. It is to be understood that the array of active channels may be a single active channel extending along the longitudinal direction and the semiconductor laser is a single channel laser.

In some embodiments, the length of the array of active channels along the longitudinal direction is in a range, for example, from 0.5 mm to 5 mm. In some embodiments, the width of the array of active channels along the transverse direction is in a range, for example, from 0.25 mm to 10 mm.

According to some embodiments, each of the active channels includes a grating positioned along the longitudinal direction. The gratings of the active channels each have a periodic structure with a target pitch corresponding to a channel lasing wavelength. The pitch of grating in each channel of the laser array can be different, which corresponds to different channel lasing wavelengths/frequencies. In some embodiments, a channel spacing of the channel lasing wavelengths/frequencies between adjacent channels is in a range, for example, 3 GHz to 500 GHz.

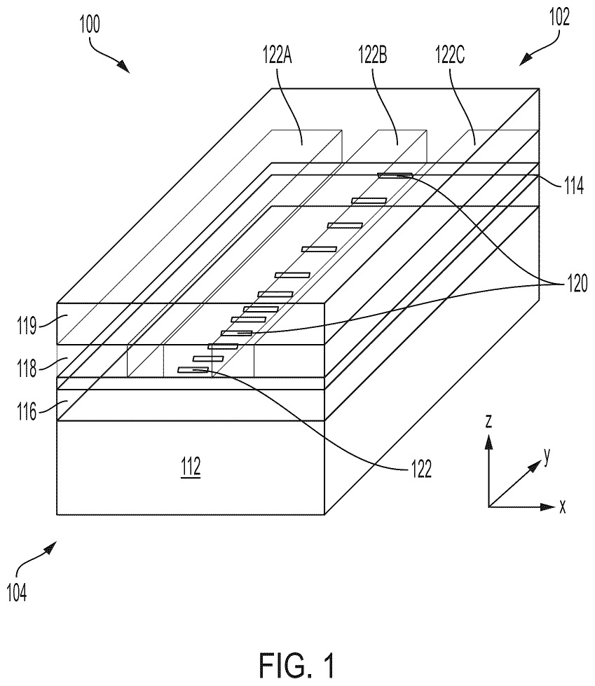

FIG. 1 is a schematic diagram illustrating an example CW DFB laser 100, in accordance with an embodiment of the present disclosure. The example semiconductor laser 100 includes an active layer 114, an n-type cladding layer 116, a p-type cladding layer 118, a semiconductor substrate 112, and an electrode layer 119. The laser 100 has a transverse direction in the direction of an x axis, a longitudinal direction in the direction of a y axis, and a thickness direction in a z axis. The active layer 114 is bounded in a longitudinal direction by a front facet 102 and a rear facet 104. In some embodiments, n-type cladding layer 116 is positioned below the active layer 114 and the p-type cladding layer 118 is positioned above the active layer 114. The active layer 114 may form a quantum well structure.

In some embodiments, the semiconductor laser 100 may have a ridge waveguide structure. In some embodiments, the semiconductor laser 100 may have a buried heterostructure structure. Exemplary materials for the n-type cladding layer 116 include III-V material. Exemplary materials for the p-type cladding layer 118 include III-V material. Exemplary materials for the active layer 114 include III-V material. Exemplary materials for the semiconductor substrate 112 include III-V material such as, for example, InP.

The front facet 102 of the semiconductor optical device 100 may be configured to emit a beam of light from the semiconductor optical device 100. In some embodiments, the front facet 102 may have a low-reflection coating provided thereon. Exemplary low-reflection coatings reflect up to about 1%, 2%, 3%, etc. of incident light. In an embodiment, the front facet 102 may be at least substantially flat. In an embodiment, the front facet 102 may be formed by etching, for example. For example, at least substantially flat shape of the front facet 102 may be formed by an etching process used to form the front facet 102. In another embodiment, the front facet 102 may be cleaved.

In some embodiments, the rear facet 104 of the semiconductor optical device 100 may be a non-emitting facet configured to reflect light back into the semiconductor optical device 100. The rear facet 104 may be highly reflective. In an embodiment, rear facet 104 may have high-reflection or anti-reflection coating provided thereon. Exemplary high-reflection coatings reflect up to about 95% incident light. In another embodiment, the rear facet 104 of the semiconductor optical device 100 may have a medium-reflection coating provided thereon. Exemplary medium-reflection coatings reflect up to 60%, 70%, 80%, 90%, etc. In other embodiments, other suitable high-reflection or medium-reflection coatings may be utilized.

In some embodiments, the p-type cladding layer 118 forms a ridge-waveguide configuration including an array of ridges 122 (122A, 122B, 122C . . . ) and gratings 120 disposed along the respective ridges along the longitudinal direction (i.e., the y axis) for each active channel. In the embodiment of FIG. 1, a single channel laser is formed by providing the gratings 120 to one channel (e.g., the channel having the ridge 122B). It is to be understood that the semiconductor optical device 100 can be a multi-channel laser by providing the gratings 120 to each channel, e.g., along the respective ridges 122.

In some embodiments, the gratings 120 of an active channel have a periodic structure with a target pitch corresponding to a channel lasing wavelength. The pitch of the gratings of a channel is defined as the periodic spacing between adjacent grating elements (e.g., stripes) in the grating structure of the active channel. In embodiments, the constant pitch is about 200 nanometers (nm) although longer or shorter pitches may be implemented. In embodiments, the gratings 120 may be a chirped grating having a non-constant pitch. The DFB gratings have a non-constant pitch deviated from the target pitch corresponding to the channel lasing wavelength. The non-constant pitch can be deviated from the target pitch by a pitch adjustment value which can be determined based at least in part on a spatial variance in a parameter of the active channel associated with operating of the semiconductor laser 100.

According to certain embodiments, for a multi-channel laser, the gratings of the active channels each have a chirped grating to compensate an inhomogeneity effect such as, for example, inhomogeneous strain and thermal conditions around the laser cavity or channel. In some embodiments, the gratings of a channel have a non-constant pitch deviated from the target pitch corresponding to the respective channel lasing wavelength. The non-constant pitch can be deviated from the target pitch by a pitch adjustment value at each section of the channel. The pitch adjustment values can be determined based at least in part on a spatial variance in a parameter of the active channels along one or both the longitudinal direction and the transverse direction of the laser array.

In some embodiments, the spatial variance in the parameter of the active channels associated with operating of the semiconductor laser includes a temperature spatial variance along one or both the longitudinal direction and the transverse direction.

According to certain embodiments, a temperature profile pitch compensation includes one or both compensations based on the longitudinal temperature profile and transverse temperature profile. In some embodiments, the compensation based on a transverse temperature profile can correct emitting wavelengths to be substantially the same as the respective target wavelengths. In some embodiments, the compensation based on a longitudinal temperature profile can reduce the effect of grating phase variation to achieve kink-free operation.

In some embodiments, pitch adjustment values at each section of a laser array can be derived from one or more temperature profiles including, for example, a longitudinal temperature profile and a transverse temperature profile (e.g., from simulations and/or measurement results). The pitch adjustment values can be applied to the original target pitches to obtain the compensated gratings for each channel. In some embodiments, the pitch adjustment can be implemented by changing the pitch values on an electron-beam lithography (EBL) mask of the gratings, which is later used in a grating writing process to form a chirped grating. With respect to a baseline temperature (i.e., no thermal gradient or heating), a positive pitch adjustment value corresponds to a temperature increase by heating from the operation. In some embodiments, the pitch adjustment value is in a range from about 0 nm to about 0.8 nm for the temperature spatial variance in a range from 0 to 40° C. In an embodiment, a pitch adjustment value of 0.15 nm may correspond to a temperature increase of about 5° C.

In some embodiments, the spatial variance in the parameter of the active channels associated with operating of the semiconductor laser includes a strain spatial variance along one or both the longitudinal direction and the transverse direction.

In some embodiments, the pitch adjustment values at each section of a laser array can be derived from one or more strain profiles of the laser array (e.g., from simulations and/or measurement results). The pitch adjustment values can be applied to the original target pitches to obtain the compensated gratings for each channel. In some embodiments, the pitch adjustment can be implemented by changing the pitch values on an electron-beam lithography (EBL) mask of the gratings, which is later used in a grating writing process to form a chirped grating. In some embodiments, the pitch adjustment value is in a range from about −2 nm to about 2 nm for the strain spatial variance in a range from about −1.0 % to about 1.0 %.

In some embodiments, the spatial variance in the parameter of the active channels associated with operating of the semiconductor laser includes a combination of a temperature spatial variance and a strain spatial variance along one or both the longitudinal direction and the transverse direction.

In some embodiments, the spatial variance in the parameter of the active channels associated with operating of the semiconductor laser includes a current density induced refractive index spatial variance along one or both the longitudinal direction and the transverse direction.

In some embodiments, the pitch adjustment values at each section of a laser array can be derived from one or more refractive index profiles (e.g., from simulations and/or measurement results). In embodiments, a refractive index spatial variance may be induced by a current density from the laser operation. The pitch adjustment values can be applied to the original target pitches to obtain the compensated gratings for each channel. In some embodiments, the pitch adjustment can be implemented by changing the pitch values on an electron-beam lithography (EBL) mask of the gratings, which is later used in a grating writing process to form a chirped grating. In some embodiments, the pitch adjustment value is in a range from about −0.3 nm to about +0.3 nm for a refractive index spatial variance in a range from 5×10⁻³ to +5×10⁻³.

In some embodiments, the pitch adjustment values at each section of a laser array can be derived from a combination of one or more temperature profiles, one or more strain profiles, and one or more refractive index profiles of the laser array (e.g., from simulations and/or measurement results). The pitch adjustment values can be applied to the original target pitches to obtain the compensated gratings for each channel. In some embodiments, the pitch adjustment can be implemented by changing the pitch values on an electron-beam lithography (EBL) mask of the gratings, which is later used in a grating writing process to form a chirped grating. In some embodiments, the pitch adjustment value is in a range from about −2 nm to about 2.8 nm for the combination of a temperature spatial variance in a range from about 0 to about 40° C. and a strain spatial variance in a range from about −1.0% to about 1.0%.

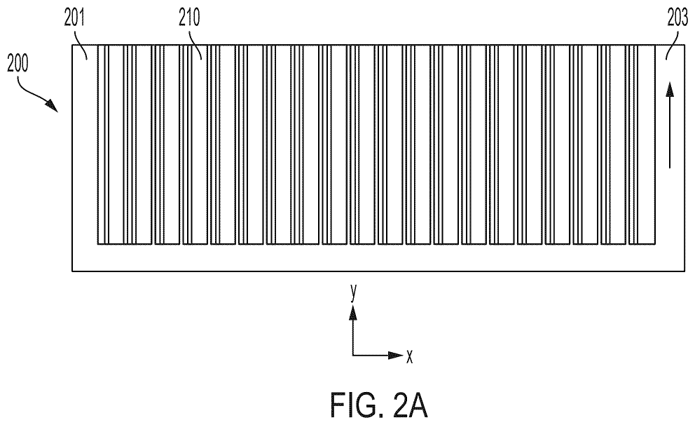

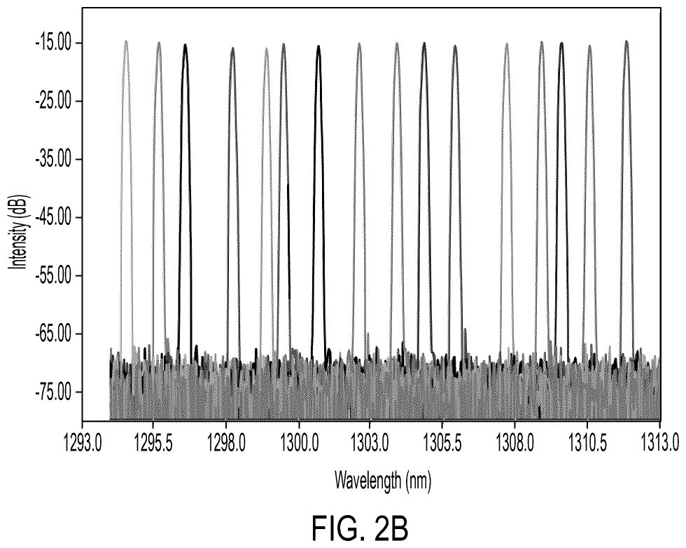

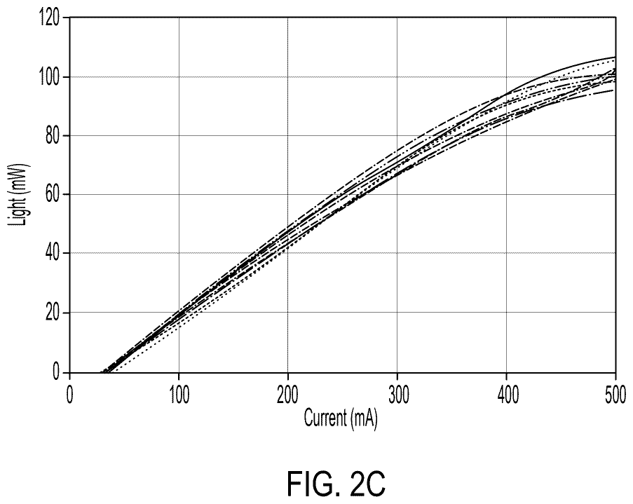

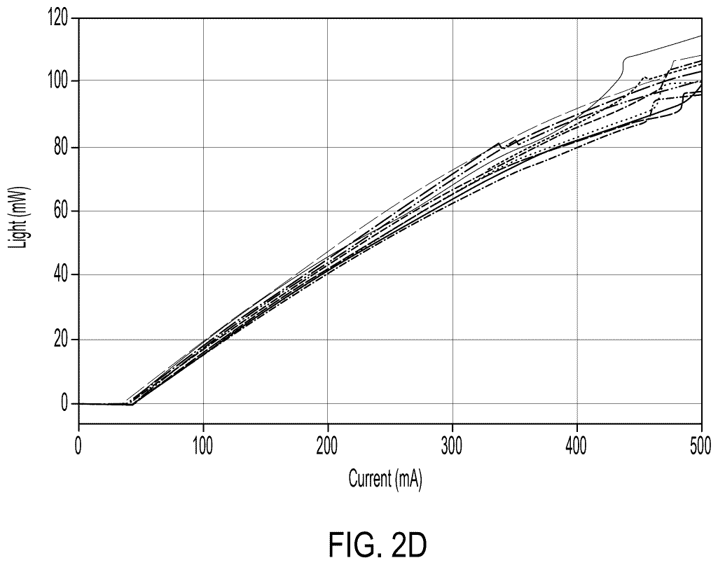

FIG. 2A is a diagram illustrating an example continuous wave (CW) distributed feedback (DFB) laser array 200, in accordance with an embodiment of the present disclosure. The example laser array 200 includes twenty channels 210 in total although other numbers of channels may be implemented. The channels 210 include sixteen laser channels in the center, two channels on one side 201, and two channels on the opposite side 203. The sixteen laser channels in the center are active channels although other numbers of active channels may be implemented. Two channels on each end or side 201/203 are alignment lasers. In one example, the spacing between adjacent channels is about 125 micrometers although other spacing values may be implemented. The laser array 200 has a total width of about 3 mm although other total width values may be implemented. Each laser cavity or channel 210 is about 900 micrometers long although other channel length values may be implemented.

In some embodiments, each of the gratings of the array of active channels 210 has a periodic structure with a target pitch corresponding to a channel lasing wavelength. The pitch of grating in each channel 210 of the laser array 200 is different, which corresponds to different channel lasing wavelengths/frequencies. For example, FIG. 2B is plots of emission spectrum of the CW DFB laser array 200 of FIG. 2A. The sixteen different wavelengths of emission from the respective active channels 210 are supported simultaneously. Each active channel 210 emits at the targeted wavelength/frequency which can be defined, for example, by the industry standard (e.g., MSA standard). In an embodiment, adjacent channel lasing wavelengths/frequencies are separated by about 200 GHz.

In some embodiments, the DFB gratings of each active channel 210 of the laser array 200 have a non-constant pitch deviated from the target pitch to compensate inhomogeneity effects such as, for example, under inhomogeneous strain and thermal conditions around the laser cavity. The non-constant pitch can be deviated from the target pitch by a pitch adjustment value which can be determined based at least in part on a spatial variance in a parameter of the active channel associated with operating of the semiconductor laser. FIG. 2C is plots illustrating a light-current (LI) characteristic of the CW DFB laser array 200 of FIG. 2A. The LI curves for all the active channels are kink-free in the operating range. The laser array 200 can support 75 mW output of all the active channels simultaneously at 55° C. FIG. 2D is plots illustrating a light-current (LI) characteristic of the comparative CW DFB laser array without the pitch compensation. The comparative CW DFB laser array has substantially the same configuration as the laser array 200 but without the pitch compensation. As a comparison, the comparative CW DFB laser array of FIG. 2D without compensation exhibits kinks on the light-current (LI) characteristic thereof.

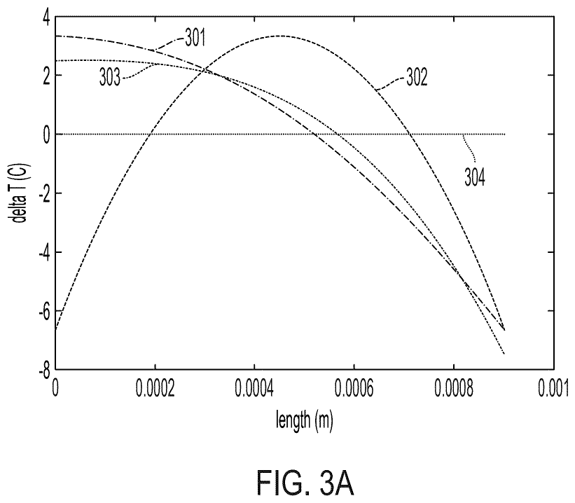

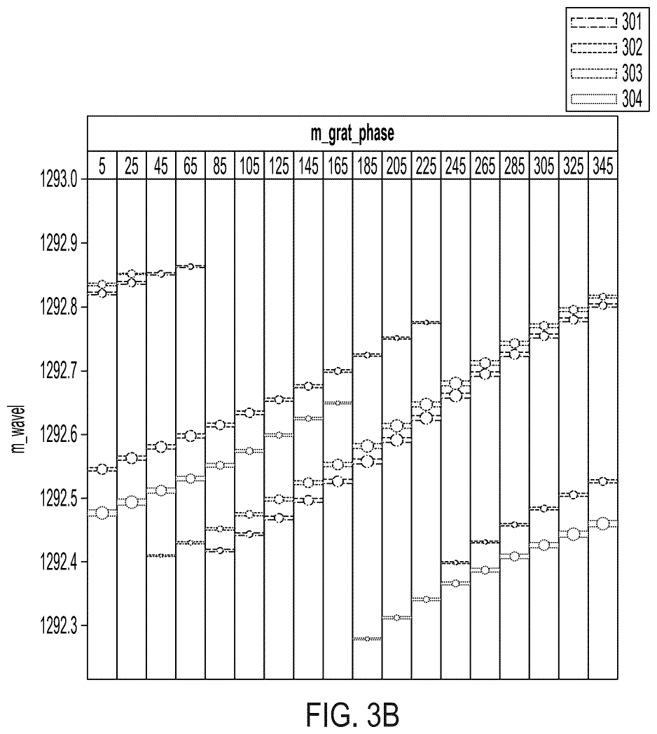

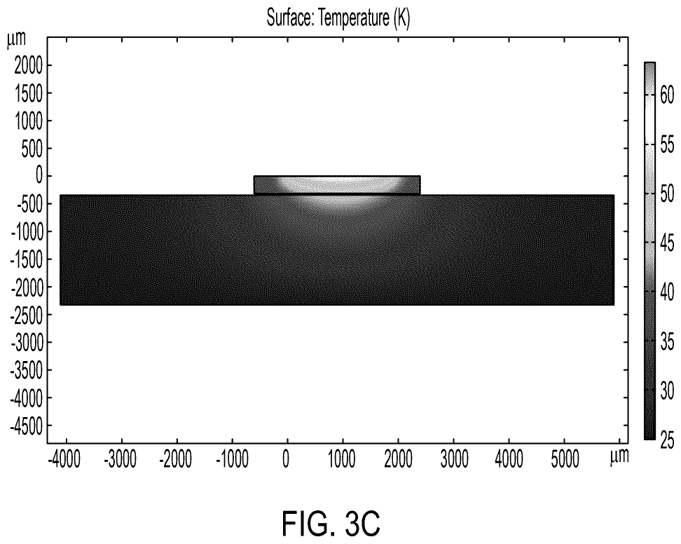

In some embodiments, one or more temperature profiles in one or both directions of the longitudinal direction and the transverse direction are generated, which are used to determine the compensation needed (e.g., by changing/adjusting pitch values) to form the temperature-profile compensated gratings of a laser array. For example, FIG. 3A is a plot illustrating example temperature profiles along each laser cavity or channel in the longitudinal direction, in accordance with an embodiment of the present disclosure. Example temperature profiles 301 and 303 each represent an asymmetric temperature profile of arrays on sub-mounts where the front facet of the laser is relatively hotter during operation. Example temperature profile 302 represents a symmetric temperature profile which is induced during a laser device test. Example temperature profile 304 represents a baseline condition without a temperature gradient in the longitudinal direction.

In some embodiments, the lasing mode wavelengths with respect to different grating phases and the relative stability of the modes can be determined for various compensated gratings. A grating phase is defined as the relative position between a grating (e.g., a notch of the grating) and a highly reflective (HR) coating (e.g., at a rear facet of the laser).

FIG. 3B is a plot illustrating calculated lasing mode wavelengths with respect to different grating phases, corresponding to the example temperature profiles 301-304 of FIG. 3A. At each grating phase, the stability of the respective modes is represented by the thickness of the bar in the plot. That is, thicker bars represent more stable a lasing mode, which may be less likely to jump to other modes. As shown in the plots of FIG. 3B, for example temperature profiles 301 and 303 of FIG. 3A, the respective modes that were stable under nominal conditions (e.g., the baseline condition represented by example temperature profile 302) become unstable. That is, operations with example temperature profiles 301 and 303 may cause discrepancies in the laser performance when operation conditions are changed, for example, from a laser test condition to a customer's end use condition. For example, in some instances, undesired kinks in LI curves may emerge in the customer's end use condition such as shown in FIG. 2D.

In some embodiments, adjustment in the pitch values of the gratings can be determined based at least in part on one or more temperature profiles under different conditions. The gratings with the adjusted pitch values can compensate the effects induced by the temperature profiles (e.g., the asymmetric temperature profiles 301 and 303) to bring the performance of the laser array back to a nominal condition (e.g., under the baseline condition represented by example temperature profile 302). The mode wavelengths under temperature profile 302 (i.e., a baseline condition) show substantially the same pattern as that of temperature profile 304 (i.e., a laser test condition). The corresponding adjustments in the pitch values of the gratings can improve laser performance (e.g., kink-free LI curves) in both a laser test condition and a customer's use condition.

In some embodiments, adjustment in the pitch values of the gratings of a laser array can be determined based at least in part on a first temperature profile and a second temperature profile. The first temperature profile can be along the longitudinal direction of the laser array. Example first temperature profiles 301-303 are shown in FIG. 3A. The second temperature profile can be along the transverse direction of the laser array. FIG. 3C is a cross-sectional map illustrating a cross-sectional temperature profile of a 16-channel laser array, in accordance with an embodiment of the present disclosure. In some instances, when multiple active channels are turned on at the same time, the first temperature profile is created along the longitudinal direction for each active channel, and the second temperature profile is created across the laser array, i.e., in the transverse direction. The values in the first and second temperature profiles can be extracted and used to determine the pitch compensation values for the DFB grating design.

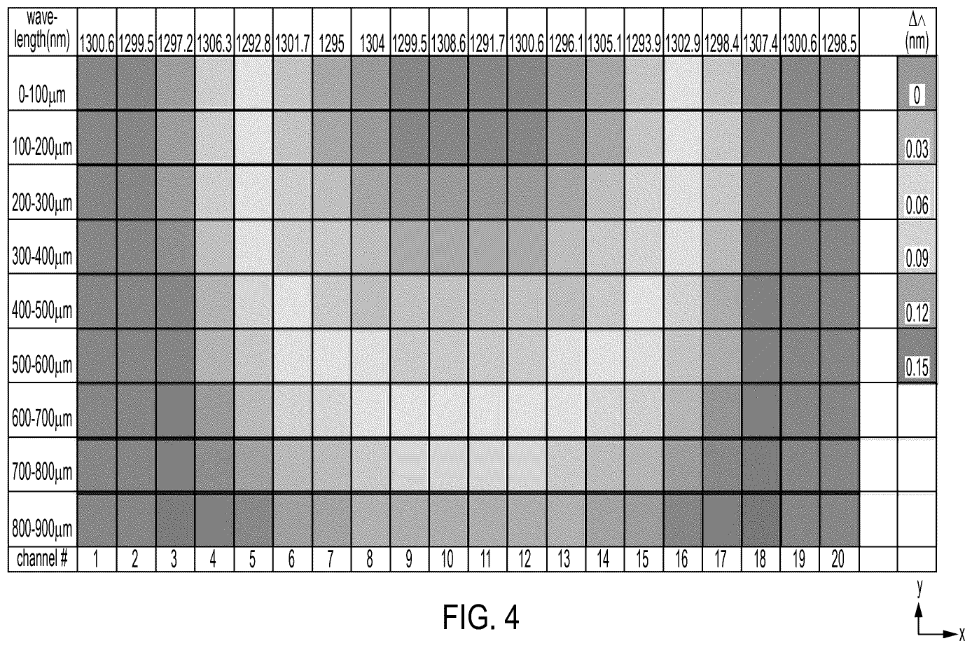

FIG. 4 is a diagram illustrating a map of pitch adjustment values (nm) in a CW DFB grating at each section of a laser array, in accordance with an embodiment of the present disclosure. The laser array has twenty channels (channels 1, 2, 3 . . . 20), where channels 1, 2 and 19, 20 on each side are for alignment, and channels 3 to 18 are active channels. The pitch adjustment or compensation values in the map can be determined based on one or more temperature profiles in the longitudinal direction and in the transverse direction such as the temperature profiles shown in FIGS. 3A and 3C.

In some embodiments, the temperature gradient of a temperature profile can be obtained by simulations and/or experimental tests. The obtained temperature profiles can be transformed by calculation into the respective pitch adjustment at each section of a laser array, based at least in part on the physical relation between a temperature value and a target wavelength, between a pitch and a target wavelength, and the like, which may include empirical equations derived from experiment tests and/or simulations. In some embodiments, the respective pitch adjustment values can be obtained from a LUT of prior trial experiment tests. In some embodiments, the respective pitch adjustment ΔΛ₁/Λ can be obtained from ΔΛ₁/Λ=−Δn/n, where Δn/n refers to a relative refractive index change given the temperature profile and can be derived from simulations.

In some embodiments, one or more strain profiles of a laser array can be obtained by simulations and/or experimental tests. The strain profile can include a strain spatial variance along one or both the longitudinal direction and the transverse direction of the laser array. The obtained strain profiles can be transformed by calculation into the respective pitch adjustment at each section of the laser array, based at least in part on the physical relation between a strain value and a target wavelength, between a pitch and a target wavelength, and the like, which may include empirical equations derived from experiment tests and/or simulations. In some embodiments, the respective pitch adjustment values can be obtained from a LUT of prior trial experiment tests. In some embodiments, the respective pitch adjustment ΔΛ₂/Λ can be obtained from ΔΛ₂/Λ=−Δn/n, where Δn/n refers to a relative refractive index change given the strain profile and can be derived from simulations.

In some embodiments, one or more refractive index profiles of a laser array can be obtained by simulations and/or experimental tests. The refractive index profile can include a current density induced refractive index spatial variance along one or both the longitudinal direction and the transverse direction of the laser array. The obtained refractive index profiles can be transformed by calculation into the respective pitch adjustment at each section of the laser array, based at least in part on the physical relation between a refractive index value and a target wavelength, between a pitch and a target wavelength, and the like, which may include empirical equations derived from experiment tests and/or simulations. In some embodiments, the respective pitch adjustment values can be obtained from a LUT of prior trial experiment tests. In some embodiments, the respective pitch adjustment ΔΛ₃/Λ can be obtained from ΔΛ₃/Λ=−Δn/n, where Δn/n refers to a relative refractive index change in the refractive index profile and can be derived from simulations.

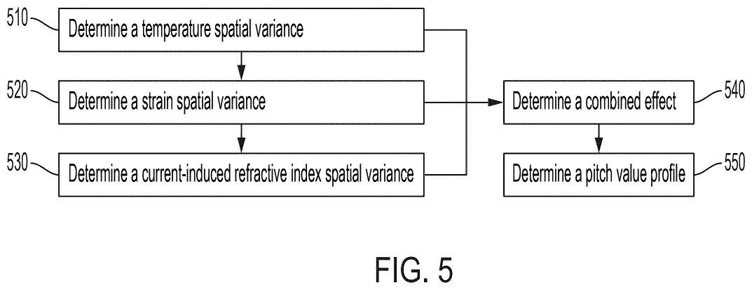

FIG. 5 is a block diagram illustrating an example method 500 of compensating parameter variance for a semiconductor laser, in accordance with an embodiment of the present disclosure. In some embodiments, the semiconductor laser includes an array of active channels at an active region. The active region has a length along a longitudinal direction thereof and a width along a transverse direction thereof. The array of active channels positioned side by side along the transverse direction with a spacing therebetween. Each of the active channels includes a plurality of gratings positioned along the longitudinal direction. Each of the pluralities of gratings of the array of active channels has a periodic structure with a target pitch corresponding to a channel lasing wavelength.

The method 500 includes determining a temperature spatial variance of the active channels (block 510). For a single-channel laser, the temperature spatial variance is along the longitudinal direction of the channel. For a multi-channel laser, the temperature spatial variance can be along one or both the longitudinal direction and the transverse direction. The temperature profile can be obtained, for example, when multiple or all active channels of the array of active channels emit light simultaneously. In some embodiments, the non-constant pitches of the array of active channels have the determined pitch value profile configured to compensate the temperature spatial variance.

The method 500 further includes determining a strain spatial variance of the active channels (block 520). The strain spatial variance can be, for example, along one or both the longitudinal direction and the transverse direction. The strain profile can be obtained, for example, when multiple or all active channels of the array of active channels emit light simultaneously. In some embodiments, the non-constant pitches of the array of active channels have a pitch value profile configured to compensate the strain spatial variance.

The method 500 further includes determining a refractive index spatial variance of the laser array (block 530). The refractive index spatial variance may be a current density induced refractive index spatial variance, for example, along one or both the longitudinal direction and the transverse direction. In some embodiments, the refractive index spatial variance may be induced by a bias current applied on an electrode layer of the semiconductor laser. The refractive index profile can be obtained, for example, when multiple or all active channels of the array of active channels emit light simultaneously. In some embodiments, the non-constant pitches of the array of active channels have a pitch value profile configured to compensate the refractive index spatial variance.

The method 500 further includes determining a combined effect (block 540). The combined effect on the laser array can be based on two or more of a temperature spatial variance of the active channels, a strain spatial variance of the active channels, and a refractive index spatial variance of the active channels. The combined effect can be determined for each section of a laser array, based at least in part on the physical relation between a temperature value and a target wavelength, between a strain value and a target wavelength, between a refractive index value and a target wavelength, between a pitch and a target wavelength, and the like, which may include empirical equations derived from experiment tests and/or simulations.

The method 500 further includes determining a pitch adjustment value profile (block 550). In some embodiments, the pitch adjustment value profile can include an array of pitch adjustment values such as shown in FIG. 4. By applying the adjustment value profile pitch to gratings of the active channels, each of the pluralities of gratings of the array of active channels has a chirped grating having a non-constant pitch. The non-constant pitch is deviated from the target pitch by a pitch adjustment value of the pitch adjustment value profile to compensate the combined effect of the spatial variances of the active channels associated with operating of the semiconductor laser. In some embodiments, the respective total pitch adjustment values can be obtained from a LUT of prior trial experiment tests. In some embodiments, the respective total pitch adjustment ΔΛ/Λ can be obtained from the summation of ΔΛ₁/Λ at block 510, ΔΛ₂/Λ at block 520, and ΔΛ₃/Λ at block 530.

An advantage, among others, of the disclosed arrayed waveguide grating device is that stability with respect to one or more parameters associated with operation of the arrayed waveguide grating device is achieved with a reduced complexity, power consumption, cost, etc. of the arrayed waveguide grating device. An advantage, among others, of the disclosed arrayed waveguide grating device is that stability with respect to an arbitrary number of parameters may be achieved without any significant increase in power consumption. An advantage, among others, of the disclosed arrayed waveguide grating device is that stability with respect to one or more parameters is achieved without a need to support additional non-optical components such as DACs, ADCs, drivers, microcontroller, etc.

While this disclosure has been described as having exemplary designs, the present disclosure can be further modified within the spirit and scope of this disclosure. This application is therefore intended to cover any variations, uses, or adaptations of the disclosure using its general principles. Further, this application is intended to cover such departures from the present disclosure as come within known or customary practice in the art to which this disclosure pertains.

We claim:

1. A semiconductor laser comprising:
an active region having a length along a longitudinal direction thereof and a width along a transverse direction thereof; and
one or more active channels each comprising a plurality of gratings positioned along the longitudinal direction,
wherein the plurality of gratings of each of the one or more active channels has a chirped grating having a non-constant pitch, the non-constant pitch being deviated from a target pitch by a pitch adjustment value based on a spatial variance in a parameter of the active channels associated with operating of the semiconductor laser, the target pitch corresponding to a channel lasing wavelength.

2. The semiconductor laser of claim 1, wherein the spatial variance in the parameter of the active channels associated with operating of the semiconductor laser includes one or more of i) a temperature spatial variance along one of the longitudinal direction and the transverse direction, ii) a strain spatial variance along one of the longitudinal direction and the transverse direction, and iii) a current density induced refractive index spatial variance along one of the longitudinal direction and the transverse direction.

3. The semiconductor laser of claim 2, wherein the pitch adjustment value is in a range from about 0 to about 0.8 nm for the temperature spatial variance in a range from 0 to 40° C.

4. The semiconductor laser of claim 2, wherein the pitch adjustment value is in a range from about −2 to about 2 nm for the strain spatial variance in a range from −1% to 1%.

5. The semiconductor laser of claim 1, wherein the spatial variance in the parameter of the active channels associated with operating of the semiconductor laser includes a combination of a temperature spatial variance and a strain spatial variance along the longitudinal direction and the transverse direction.

6. The semiconductor laser of claim 5, wherein the pitch adjustment value is in a range from about −2 to about 2.8 nm for the combination of a temperature spatial variance and a strain spatial variance along the longitudinal direction and the transverse direction.

7. The semiconductor laser of claim 1, wherein the one or more active channels are positioned side by side along the transverse direction with a spacing therebetween in a range from 20 micrometers to 250 micrometers.

8. The semiconductor laser of claim 1, wherein the length of the one or more active channels is in a range from 0.5 mm to 5 mm.

9. The semiconductor laser of claim 1, wherein the width of the one or more active channels is in a range from 0.25 mm to 10 mm.

10. The semiconductor laser of claim 1, wherein the channel lasing wavelengths of the one or more active channels have a channel spacing in a range from 3 GHz to 500 GHz.

11. The semiconductor laser of claim 1, further comprising:
a substrate;
a p-type cladding layer;
an n-type cladding layer;
an electrode layer;
wherein the active region is sandwiched between the p-type cladding layer and the n-type cladding layer, and
wherein a bias current is applied on the electrode layer.

12. A method of making a semiconductor laser, the method comprising:
forming one or more active channels at an active region, wherein:
the active region has a length along a longitudinal direction thereof and a width along a transverse direction thereof;
the one or more active channels each comprising a plurality of gratings positioned along the longitudinal direction; and
the pluralities of gratings of each of the one or more active channels has a chirped grating having a non-constant pitch, the non-constant pitch being deviated from a target pitch by a pitch adjustment value based on a spatial variance in a parameter of the active channels associated with operating of the semiconductor laser, the target pitch corresponding to a channel lasing wavelength.

13. The method of claim 12, further comprising determining a temperature spatial variance of the active channels along one of both of the longitudinal direction and the transverse direction.

14. The method of claim 13, further comprising determining the pitch adjustment value of the one or more active channels based at least in part on the temperature spatial variance.

15. The method of claim 12, further comprising determining a strain spatial variance of the active channels along one or both of the longitudinal direction and the transverse direction.

16. The method of claim 15, further comprising determining the pitch adjustment value of the one or more active channels based at least in part on the strain spatial variance.

17. The method of claim 12, further comprising determining a refractive index spatial variance along one or both of the longitudinal direction and the transverse direction.

18. The method of claim 17, wherein the refractive index spatial variance is induced by a bias current applied on an electrode layer of the semiconductor laser.

19. The method of claim 17, further comprising determining the pitch adjustment value of the one or more active channels the refractive index spatial variance.

20. The method of claim 12, further comprising determining the pitch adjustment value of the one or more active channels based on two or more of a temperature spatial variance of the active channels, a strain spatial variance of the active channels, and a refractive index spatial variance.
